(19) United States
(12) Patent Application Publication
(10) Pub. No.: US 2019/0020357 A1
(43) Pub. Date: Jan. 17, 2019

(54) Device and Method of Decoding a Raptor Code

(71) Applicants: National Taiwan University, Taipei City (TW); MEDIATEK INC., Hsin-Chu (TW)

(72) Inventors: Mao-Chao Lin, Taipei City (TW); Guan-Ting Li, Taoyuan City (TW)

(21) Appl. No.: 16/024,916

(22) Filed: Jul. 2, 2018

Related U.S. Application Data
(60) Provisional application No. 62/532,990, filed on Jul. 14, 2017.

(51) Int. Cl. H03M 13/29; H03M 13/45; H03M 13/11; H03M 13/37; H04L 1/00

(52) U.S. Cl. CPC H03M 13/2906; H03M 13/45; H03M 13/6552; H03M 13/3761; H04L 1/0058; H03M 13/1105

(57) ABSTRACT

A receiver for decoding a Raptor code comprises a first decoder, for performing following operations: receiving a first plurality of coded symbols encoded from a message according to the Raptor code; decoding the first plurality of coded symbols into a first plurality of decoded symbols; determining whether a second plurality of coded symbols are needed for the Raptor code according to a function of the first plurality of decoded symbols; and receiving the second plurality of coded symbols and decoding the first plurality of coded symbols and the second plurality of coded symbols into the first plurality of decoded symbols, if the second plurality of coded symbols are needed; and a second decoder, coupled to the first decoder, for decoding the first plurality of decoded symbols into a second plurality of decoded symbols.

### CROSS REFERENCE TO RELATED APPLICATIONS

This application claims the benefit of U.S. Provisional Application No. 62/532,990 filed on Jul. 14, 2017, which is incorporated herein by reference.

### BACKGROUND OF THE INVENTION

### 1. Field of the Invention

The present invention relates to a communication device and a method used in a communication system, and more particularly, to a communication device and a method of decoding a Raptor code.

### 2. Description of the Prior Art

Comparing with traditional error correcting codes, a Raptor code has the advantage of employing extremely small incremental redundancy (IR) for a channel capable of retransmitting additional symbols for a given message. A major problem is high complexity caused by iterative decoding of the Raptor code. Thus, how to reduce the complexity of the iterative decoding and possibly many IR symbols of the Raptor code is an important problem to be solved.

### SUMMARY OF THE INVENTION

The present invention therefore provides a method and related communication device for decoding a Raptor code to solve the abovementioned problem.

A receiver for decoding a Raptor code comprises a first decoder, for performing following operations: receiving a first plurality of coded symbols encoded from a message according to the Raptor code; decoding the first plurality of coded symbols into a first plurality of decoded symbols; determining whether a second plurality of coded symbols are needed for the Raptor code according to a function of the first plurality of decoded symbols; and receiving the second plurality of coded symbols and decoding the first plurality of coded symbols and the second plurality of coded symbols into the first plurality of decoded symbols, if the second plurality of coded symbols are needed; and a second decoder, coupled to the first decoder, for decoding the first plurality of decoded symbols into a second plurality of decoded symbols.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a communication system according to an example of the present invention.

FIG. 2 is a schematic diagram of a Raptor encoder and a Raptor decoder according to an example of the present invention.

FIG. 3 is a schematic diagram of a Tanner graph of the Raptor code according to an example of the present invention.

FIG. 4 is a schematic diagram of comparison of throughputs according to examples of the present invention.

FIG. 5 is a schematic diagram of comparison of complexities according to examples of the present invention.

FIG. 6 is a schematic diagram of comparison of complexities according to examples of the present invention.

FIG. 7 is a schematic diagram of comparison of throughputs according to examples of the present invention.

FIG. 8 is a schematic diagram of comparison of complexities according to examples of the present invention.

FIG. 9 is a schematic diagram of comparison of complexities according to examples of the present invention.

FIG. 10 is a flowchart of a process according to an example of the present invention.

### DETAILED DESCRIPTION

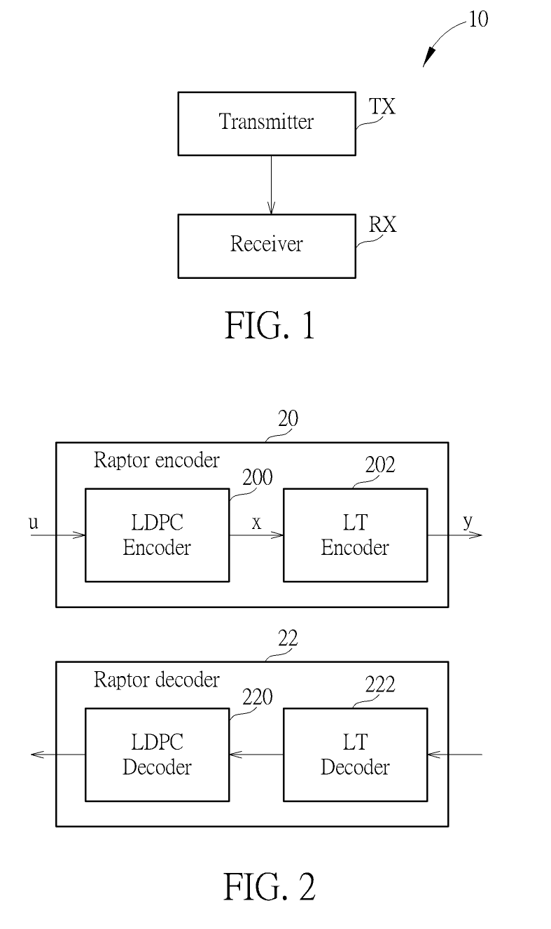

FIG. 1 is a schematic diagram of a communication system 10 according to an example of the present invention. The communication system 10 may be any (e.g., wireless or wireline) communication system (e.g., multicarrier system), and is briefly composed of a transmitter TX and a receiver RX. In FIG. 1, the transmitter TX and the receiver RX are simply utilized for illustrating the structure of the communication system 10. In one example, the communication system 10 may be an asymmetric digital subscriber line (ADSL) system, a power line communication (PLC) system, an Ethernet over coax (EOC) and other wired communication systems. In one example, the communication system 10 may be a wireless local area network (WLAN), a digital video broadcasting (DVB) system, a long term evolution (LTE) system, a LTE-advanced (LTE-A) system, a fifth generation (5G) system or other wireless communication systems, wherein the DVB system may include a DVB-Terrestrial (DVB-T) system, a DVB-T2 system, etc.

In addition, the transmitter TX and the receiver RX may be seen as a part of a base station (BS) and/or a communication device according to direction (i.e., transmission direction). For an uplink (UL), the transmitter TX is installed in the communication device, and the receiver RX is installed in the BS. For a downlink (DL), the transmitter TX is installed in the BS, and the receiver RX is installed in the communication device. In one example, the BS may be an access point (AP) in a WLAN, may be an evolved Node-B (eNB) or a relay station in a LTE system, a LTE-A system or an evolution of the LTE-A system, or may be a 5G BS in a 5G system. In one example, the communication device may be a user equipment (UE), a low cost device (e.g., machine type communication (MTC) device), a device-to-device (D2D) device, a mobile phone, a laptop, a tablet computer, an electronic book, a portable computer system or combination thereof.

FIG. 2 is a schematic diagram of a Raptor encoder 20 and a Raptor decoder 22 according to an example of the present invention. The Raptor encoder 20 can be installed in the transmitter TX, and the Raptor decoder 22 can be installed in the receiver RX. The Raptor encoder 20 includes an encoder of a high-rate channel code, e.g., a low-density parity-check (LDPC) encoder 200, and a Luby transform (LT) encoder 202. The Raptor decoder 22 includes a decoder of the high-rate channel code, e.g., a LDPC decoder 220, and a LT decoder 222. The Raptor encoder 20 and the Raptor decoder 22 operates (i.e., encodes and decodes) according to a Raptor code. The Raptor code is a type of a rateless code that is constructed by using a serial concatenation of a high-rate channel code, e.g., a LDPC code, followed by a LT code. The nature of the rateless code allows the Raptor encode to continuously output a (extremely) small amount of incremental redundancy (IR). Hence, a throughput of the Raptor code can approach a channel capacity in a wide signal-to-noise ratio (SNR) range.

When performing encoding of the Raptor code, the LDPC encoder 200 first encodes a k-bit message u=(u₁, u₂, . . . , uₖ) into a n-bit LDPC codeword x=(x₁, x₂, . . . , xₙ). Then, the LT encoder 202 encodes the LDPC codeword x into a semi-infinite binary LT codeword sequence y=(y₁, y₂, . . . ) according to a pre-designed (e.g., predetermined) degree distribution or a set of pre-designed degree distributions.

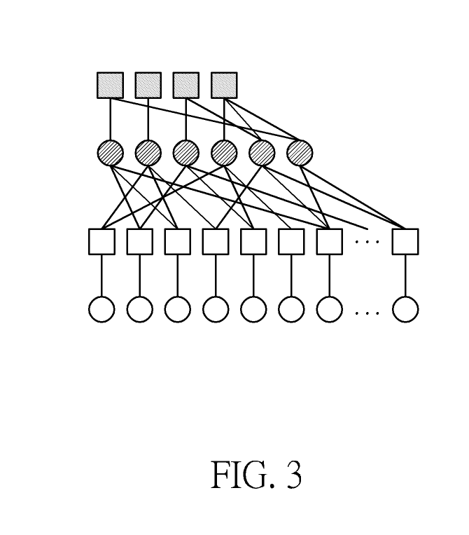

FIG. 3 is a schematic diagram of a Tanner graph of the Raptor code according to an example of the present invention. Check nodes of the LDPC code are represented by dotted boxes, and variable nodes of the LDPC code are represented by dotted circles (intermediate nodes). Check nodes of the LT code are represented by empty boxes, and transmitted (or received) symbols are represented by empty circles. For a systematic raptor code, first n LT code symbols (check nodes) are the same as the n LDPC code symbols (variable nodes), and the additional LT (redundant) symbols are derived by the connections selected according to a degree distribution.

The Raptor decoder 22 attempts to recover the message u, after some of the transmitted symbols (e.g., the codeword sequence y possibly with effects of noise and interference) are received. For the systematic Raptor code, the Raptor decoder 22 performs a first decoding attempt when n transmitted symbols are received. If the first decoding attempt is not successful, the Raptor decoder 22 collects additional δ transmitted symbols and performs a second decoding attempt. Such decoding attempt(s) is repeated until the decoding is successful, i.e., the message u is recovered. The additional δ symbols are referred to as the IR. A belief propagation (BP) decoding is performed by passing and updating log-likelihood ratios (LLRs) iteratively according to the Tanner graph.

Although for the Raptor code, a single iteration decoding loop can be employed, two iterative loops are considered in the present invention and more flexibility is achieved. One is the LT code (i.e., inner code) and the other is the LDPC code (i.e., outer code). The LT decoder 222 performs a LT decoding on the possibly error-corrupted version of encoded symbols for Lₗₜ iterations, and feeds decoding results to the LDPC decoder 220. The LDPC decoder 220 performs a LDPC decoding on the decoded results for L_{ldpc} iterations. By using check equations of the LDPC code or using a cyclic redundancy check (CRC) embedded in the message u, the receiver RX can determine whether the decoding of the message u is successful. If the decoding is successful, the receiver RX transmits an acknowledgement (ACK) to the transmitter TX. Otherwise, the receiver RX waits and collects additional δ symbols, and starts a next decoding attempt.

Hence, an early termination mechanism is proposed to terminate decoding iterations whenever it is detected that the message u is unlikely to be successfully recovered, even if the Lₗₜ iterations for the LT decoder 222 and the L_{ldpc} iterations for the LDPC decoder 220 are completed. In such a situation, a better option may be using more IR to enhance the probability of successful decoding instead of continuing the iterations without more IR.

Variation of outputs from successive iterations for the LT decoder 220 are used for an early termination in the prior art. In contrast, the present invention develops a predetermined threshold for a given number of iterations for the LT decoder 220 to determine whether the iteration is likely to be successful. In this way, the iteration may be stopped for the first iteration or the first several iterations. Such early termination mechanism is more efficient than using the outputs from the successive iterations of the LT decoder 220. However, the concept of using the outputs from the successive iterations can be incorporated into the concept of the predetermined threshold for each iteration proposed in the present invention.

Iₓ=I(U;X) is defined as mutual information between the message u and LLR values Lₓ of the intermediate nodes x. In one example, the LLR values Lₓ is Gaussian distributed with a mean (σ²/2)w and a variance σ². Suppose that the LDPC code has a code rate of 0.95. For a rate-0.95 LDPC code to obtain a close-to-zero error rate, the mutual information Iₓ=0.95 may not be enough for short code lengths. Considering that the mutual information Iₓ in a range between 0.95 and 0.98 is used as a threshold for determining whether decoding results outputted from the LT decoder 222 is appropriate for the LDPC decoder 220. Based on the mutual information Iₓ, two methods are proposed to employ the mutual information Iₓ for the early termination of the LT code.

A first method for an early termination of the LT code is proposed as follows. An average magnitude of LLR values (AML) of the LLR values Lₓ at an end of each iteration of the LT decoder 222 is used. A threshold of the AML AMLₜₕ is predetermined according to the mutual information Iₓ. If the AML is smaller than the threshold AMLₜₕ, the early termination is triggered. It means that the LDPC decoder 220 is unlikely to recover the message u by using the current outputs of the LT decoder 222 (i.e., the transmitted symbols). The AML from the mutual information Iₓ (or its corresponding σ) can be obtained according to the following equation:

$$AML = {\int }_{- ∞}^{+ ∞} \vert ξ \vert \frac{- ( {( ξ - \frac{{σ}^{2}}{2} )}^{2} / ( 2 {σ}^{2} ) )}{\sqrt{2 π} σ} d ξ \qquad ( Eq . 1 )$$

In one example, for the mutual information Iₓ=0.95, 0.96, 0.97 and 0.98, the corresponding AMLs computed according to the above equation are 9.95, 10.74, 11.78 and 13.29, respectively. The performances of the LT code using a (2000, 1900) LDPC outer code with δ=40, where the inequality L_{ldpc}≤10 means that at most 10 LDPC iterations are used while the iteration can be terminated if all the check equations are satisfied. Here, the CRC is not used. For a more accurate message recovery, the CRC can be used.

According to the above description, an example of a pseudo code for the first method can be obtained as follows:

For (i=1:Lₗₜ)

Check the AML at the end of the i-th iteration.
if (AML>AMLₜₕ)

Feed the results to the LDPC decoder.
if (The LDPC decoding is correct)

Determine that the decoding is successful.

else

Increase the redundancy.

end if

else

Increase the redundancy.

end for

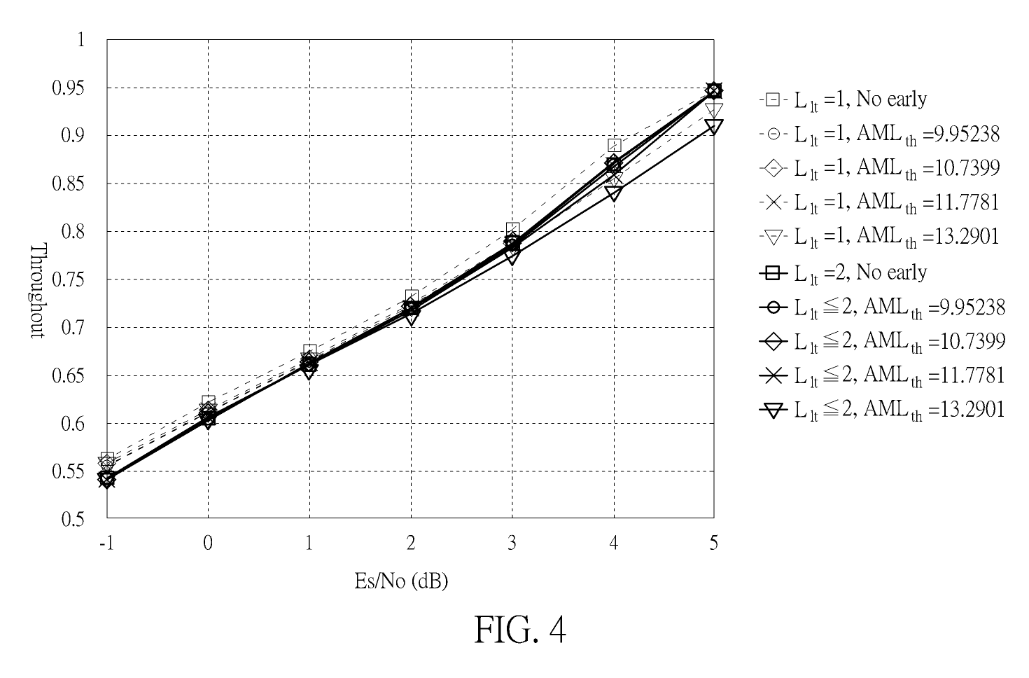

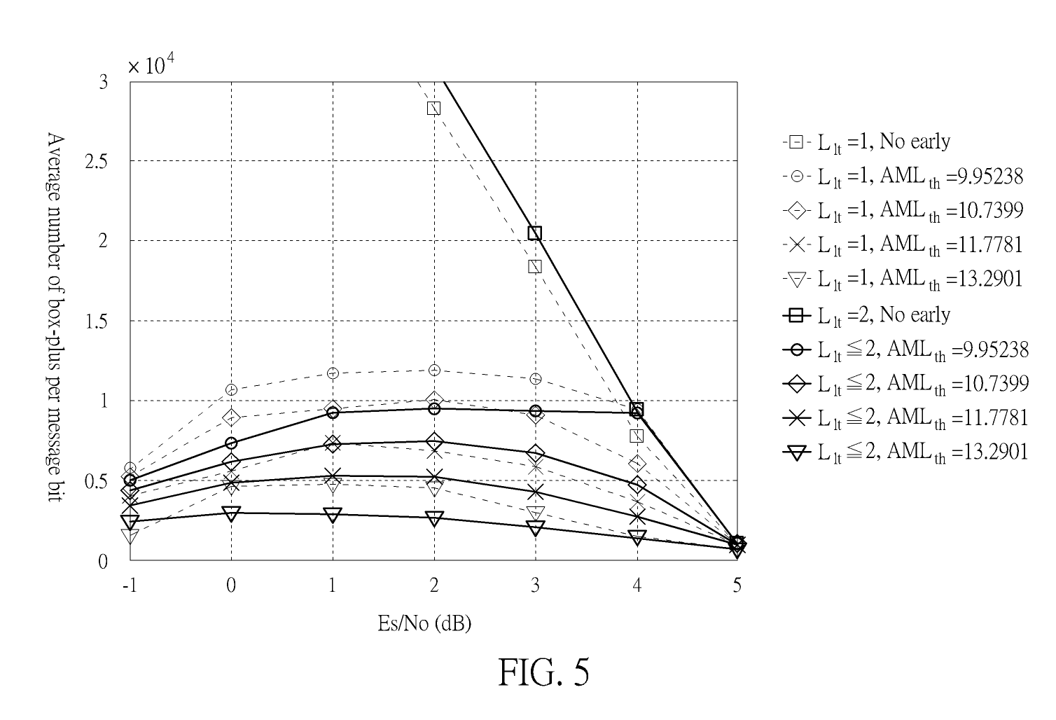

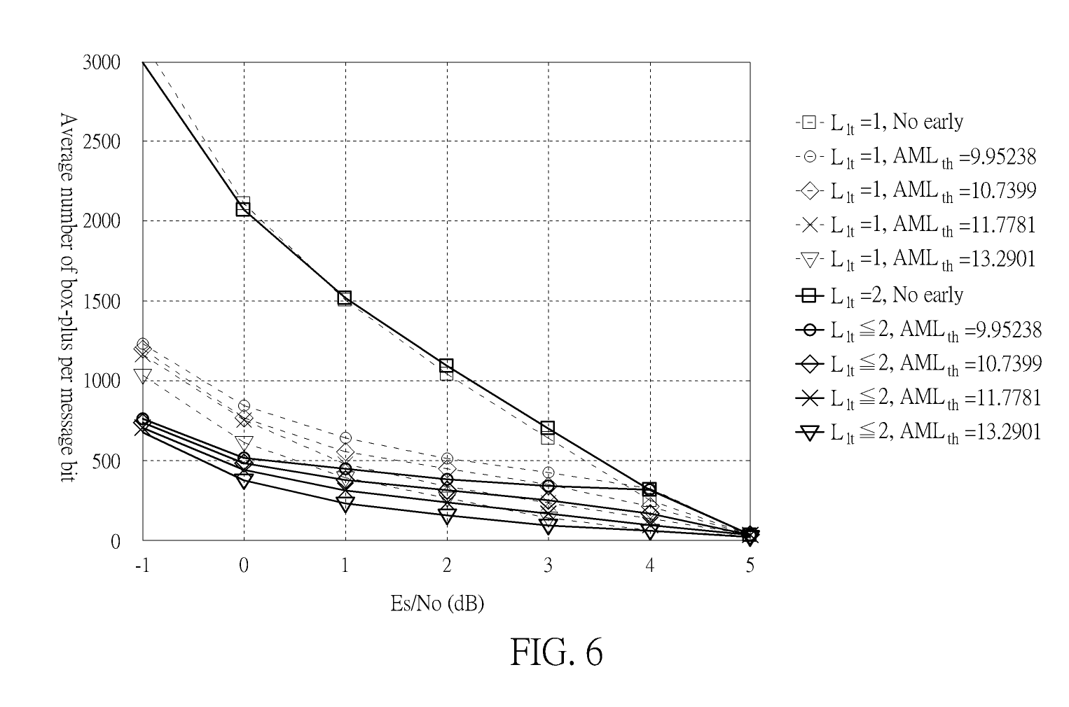

FIG. 4 is a schematic diagram of comparison of throughputs according to examples of the present invention. FIG. 5 is a schematic diagram of comparison of complexities according to examples of the present invention. An average number of box-pluses (or min-sum operations) per message bit is used as a metric for comparing the complexity. FIG. 6 is a schematic diagram of comparison of complexities according to examples of the present invention. An average number of additions per message bit is used as a metric for comparing the complexity. In FIGS. 4-6, results are obtained based on various values of Lₗₜ and the threshold AMLₜₕ. A (2000, 1900) LDPC outer code with L_{ldpc}≤10 and δ=40 is used. A systematic LT code is used in the figures.

In any scenario using the threshold AMLₜₕ in the ranges of {10.74, 11.78, 13.29}, the corresponding decoding complexity is greatly reduced as compared to the methods not using the early termination threshold (denoted as “No early”), while the degradation of the throughput is not significant. Note that for the threshold AMLₜₕ=9.95 (Iₓ=0.95), the corresponding decoding complexity is even higher than the methods not using the early termination threshold for Es/No=4 dB and Lₗₜ≤2. This phenomenon fits the assumption that the mutual information Iₓ=0.95, the code rate of the LDPC code is a critical value.

A second method for an early termination of the LDPC code is proposed as follows. Check sum equations corresponding to check nodes of the LDPC code at the end of each iteration of the LT decoder 222 is used. The number of unsuccessful check nodes (UCNs) is computed. A predetermined threshold of the UCN UCNₜₕ is set for determining whether the early termination is needed. If the number of UCNs is not smaller than the threshold UCNₜₕ, the early termination is triggered. A bit error rate (BER) of intermediate nodes may be estimated according to the following equation:

$${p}_{x} = \frac{1}{2} erfc ( \frac{σ}{2 \sqrt{2}} ) \qquad ( Eq . 2 )$$

A probability for a check node with a degree d to have a non-zero check sum may be estimated according to the following equation:

P_{NZ}=Σᵢ₌₁^{[d/2]}C₂ᵢ₋₁^{d}pₓ²ⁱ⁻¹(1−pₓ)^{d-2i+1} (Eq. 3)

In one example, it is assumed that the probability P_{NZ} is independent of other check nodes and an average value of the degree d over all check nodes is used for computing the probability P_{NZ}. Then, the average of the number of UCNs may be estimated according to the following equation:

AUCN=(n−k)P_{NZ} (Eq. 4)

In one example, for a (2000, 1900) LDPC code, the average value of the degree d is 60. Hence, for the mutual information Iₓ=0.95, 0.96, 0.97 and 0.98, the corresponding AUCN are 39.71, 35.72, 30.22 and 22.62, respectively. The threshold UCNₜₕ can be set to 40, 35, 30 and 23 according to the corresponding AUCN, respectively.

According to the above description, an example of a pseudo code for the second method can be obtained as follows:

For (i=1:Lₗₜ)

Check the UCL at the end of the i-th iteration.
if (the average number of UCNs<UCNₜₕ)

```
  Feed the results to the LDPC decoder.
  if (The LDPC decoding is correct)
```

Determine that the decoding is successful.

else

Increase the redundancy.

end if

else

Increase the redundancy.

end for

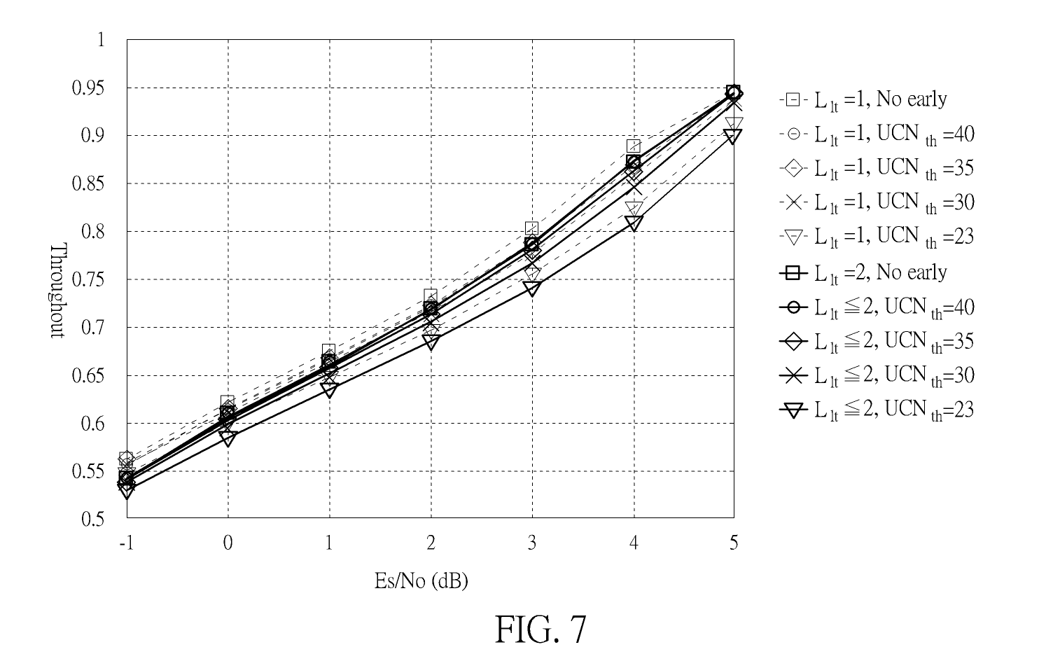

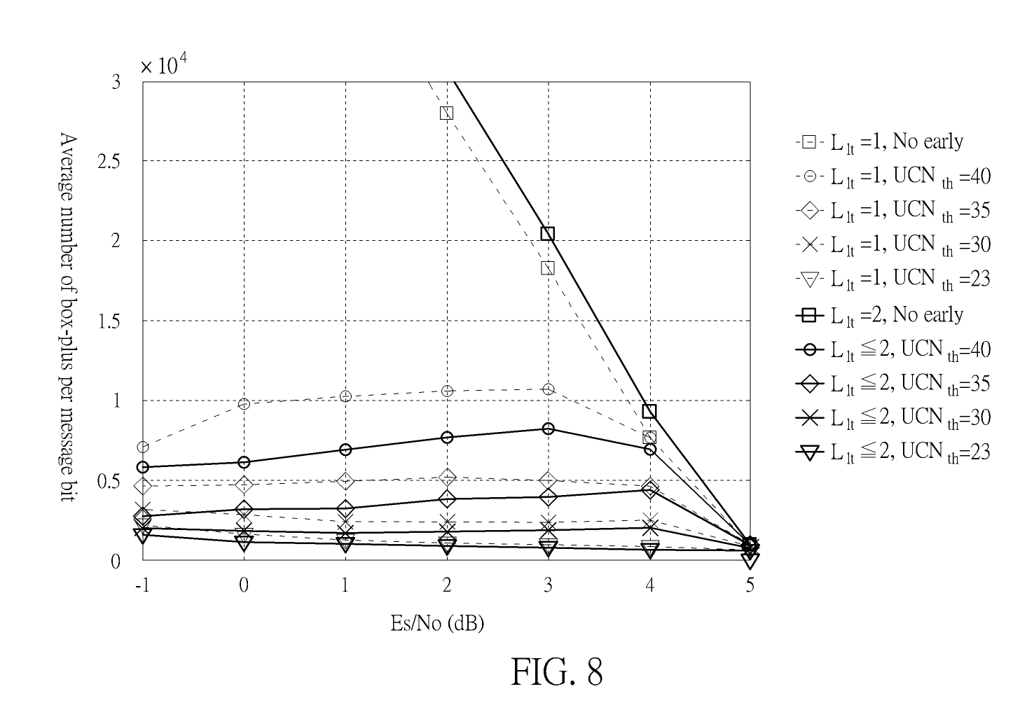

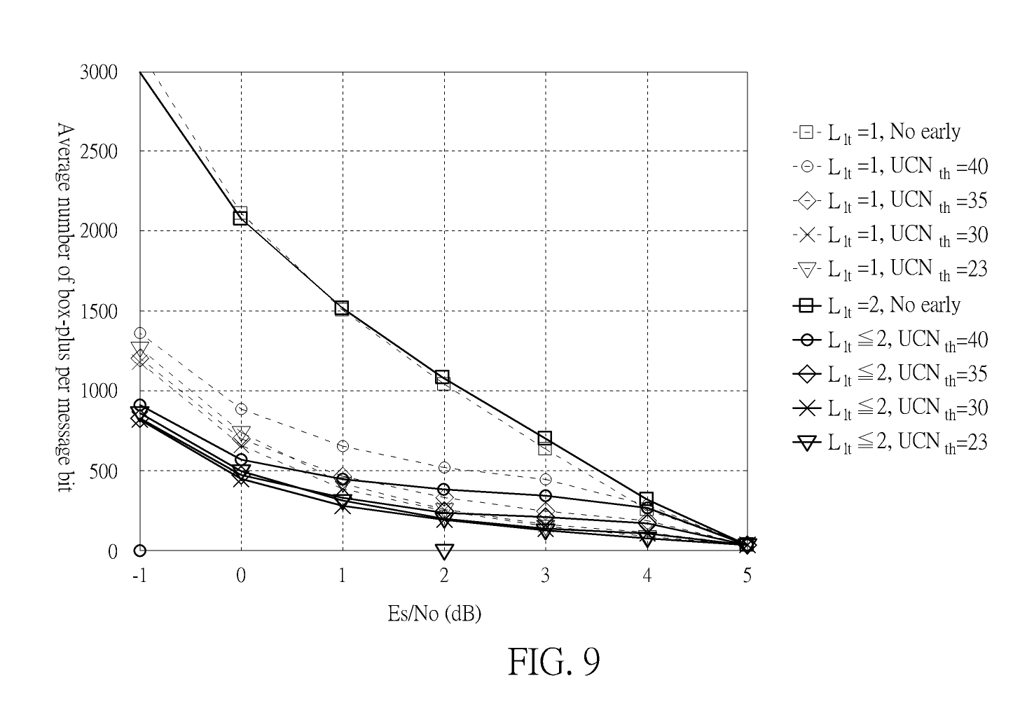

FIG. 7 is a schematic diagram of comparison of throughputs according to examples of the present invention. FIG. 8 is a schematic diagram of comparison of complexities according to examples of the present invention. An average number of box-pluses (or min-sum operations) per message bit is used as a metric for comparing the complexity. FIG. 9 is a schematic diagram of comparison of complexities according to examples of the present invention. An average number of additions per message bit is used as a metric for comparing the complexity. In FIGS. 7-9, results are obtained based on various values of Lₗₜ and the threshold AMLₜₕ. A (2000, 1900) LDPC outer code with L_{ldpc}≤10 and δ=40 is used. A systematic LT code is used in the figures.

The results show that performance improvement of using the threshold UCNₜₕ is similar to that of using the threshold AMLₜₕ. Compared to the early termination using only the variation of successive iterations, the stopping criterion proposed in the present invention can be activated for the first iteration if the input to the intermediate nodes is weak.

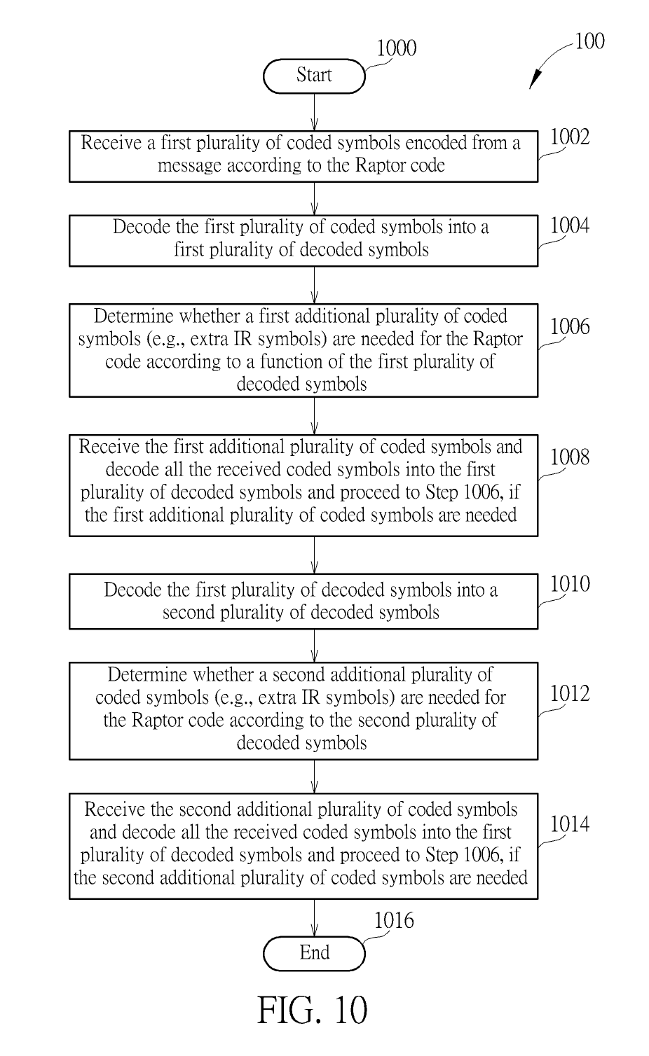

Operations of the Raptor decoder 22 regarding the first method and the second method can be summarized into a flowchart of a process 100 shown in FIG. 10, which includes the following steps:

Step 1000: Start.

Step 1002: Receive a first plurality of coded symbols encoded from a message according to the Raptor code.

Step 1004: Decode the first plurality of coded symbols into a first plurality of decoded symbols.

Step 1006: Determine whether a first additional plurality of coded symbols (e.g., extra IR symbols) are needed for the Raptor code according to a function of the first plurality of decoded symbols.

Step 1008: Receive the first additional plurality of coded symbols and decode all the received coded symbols into the first plurality of decoded symbols and proceed to Step 1006, if the first additional plurality of coded symbols are needed.

Step 1010: Decode the first plurality of decoded symbols into a second plurality of decoded symbols.

Step 1012: Determine whether a second additional plurality of coded symbols (e.g., extra IR symbols) are needed for the Raptor code according to the second plurality of decoded symbols.

Step 1014: Receive the second additional plurality of coded symbols and decode all the received coded symbols into the first plurality of decoded symbols and proceed to Step 1006, if the second additional plurality of coded symbols are needed.

Step 1016: End.

For the first method, the function of the first plurality of decoded symbols is an AML of the first plurality of decoded symbols. The first decoder determines that the second plurality of coded symbols are needed, if the AML of the first plurality of decoded symbols is not greater than a predetermined AML threshold. The predetermined AML threshold is obtained according to a mutual information of the second plurality of decoded symbols and the message.

For the second method, the function of the first plurality of decoded symbols is a number of UCNs of the first plurality of decoded symbols. The first decoder determines that the second plurality of coded symbols are needed, if the number of UCNs is not smaller than a predetermined UCN threshold. The number of UCNs is obtained according to a BER of the first plurality of decoded symbols and a degree of the seconder decoder.

Detailed operations and variations of the process 100 can be referred to the above illustration, and are not narrated herein.

It should be noted that realizations of the transmitter TX (including the Raptor encoder 20, the LDPC encoder 200 and the LT encoder 20) and the receiver RX (including the Raptor decoder 22, the LDPC decoder 220, and the LT decoder 222) are not limited to the above description. For example, two or more of the abovementioned units may be integrated into one or more units according to design considerations and/or system requirements. In addition, the transmitter TX (or the receiver RX) maybe hardware (e.g., circuit), software, firmware (known as a combination of a hardware device and computer instructions and data that reside as read-only software on the hardware device), an electronic system, combination thereof, etc.

To sum up, the present invention provides a device and a method of for decoding a Raptor code. Complexity of iterative decoding of the Raptor code can be reduced according to an early termination. Thus, power consumption can be saved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A receiver for decoding a Raptor code, comprising:
a first decoder, for performing following operations:
receiving a first plurality of coded symbols encoded from a message according to the Raptor code;
decoding the first plurality of coded symbols into a first plurality of decoded symbols;
determining whether a second plurality of coded symbols are needed for the Raptor code according to a function of the first plurality of decoded symbols; and
receiving the second plurality of coded symbols and decoding the first plurality of coded symbols and the second plurality of coded symbols into the first plurality of decoded symbols, if the second plurality of coded symbols are needed; and
a second decoder, coupled to the first decoder, for decoding the first plurality of decoded symbols into a second plurality of decoded symbols.

2. The receiver of claim 1, wherein the function of the first plurality of decoded symbols is an average magnitude of log-likelihood ratio (LLR) values (AML) of the first plurality of decoded symbols.

3. The receiver of claim 2, wherein the first decoder determines that the second plurality of coded symbols are needed, if the AML of the first plurality of decoded symbols is not greater than a predetermined AML threshold.

4. The receiver of claim 3, wherein the predetermined AML threshold is obtained according to a mutual information of the second plurality of decoded symbols and the message.

5. The receiver of claim 1, wherein the function of the first plurality of decoded symbols is a number of unsuccessful check nodes (UCNs) of the first plurality of decoded symbols.

6. The receiver of claim 5, wherein the first decoder determines that the second plurality of coded symbols are needed, if the number of UCNs is not smaller than a predetermined UCN threshold.

7. The receiver of claim 5, wherein the number of UCNs of the first plurality of decoded symbols is obtained according to a bit error rate (BER) of the first plurality of decoded symbols and a degree of the second decoder.

8. The receiver of claim 1, wherein the first decoder is a Luby transform (LT) decoder.

9. The receiver of claim 1, wherein the second decoder is a low-density parity-check (LDPC) decoder.

10. The receiver of claim 1, wherein the first plurality of coded symbols is comprised in a semi-infinite binary codeword sequence.

11. The receiver of claim 1, wherein the Raptor code is a systematic Raptor code.
